(19) United States
(12) Patent Application Publication
(10) Pub. No.: US 2012/0190180 A1
(43) Pub. Date: Jul. 26, 2012

(54) Thin film crystallization device and method for making a polycrystalline composition

(76) Inventors: Joseph D. LoBue, Dale, TX (US); Dingyuan Lu, Austin, TX (US); Louay Eldada, Austin, TX (US)

(21) Appl. No.: 12/931,067

(22) Filed: Jan. 24, 2011

(51) Int. Cl. H01L 21/20; H01B 1/02; B01J 19/00; H01B 1/00

(52) U.S. Cl. 438/486; 252/500; 252/512; 252/514; 422/198; 257/E21.133

(57) ABSTRACT

A method for making a polycrystalline composition, wherein the method includes the steps of a) preparing a precursor material, b) heating the precursor material to a reaction temperature in the presence of a precursor vapor supplied from a source at a preselected partial pressure, for a sufficient time to initiate an interaction between the precursor material and the precursor vapor to form a heated precursor material, and c) cooling the heated precursor material at a predetermined cooling rate, optionally, in the presence of the precursor vapor supplied at a partial pressure, to yield the polycrystalline composition. A device for implementing the method of the present invention is also provided

### FIELD OF THE INVENTION

The present invention relates to material processing, and more particularly a device and method for making a polycrystalline composition.

### BACKGROUND OF THE INVENTION

Semiconductor materials, typically in the form of crystalline solids, provide the basis for many applications in modern electronics including transistors, solar cells, diodes and other devices. Semiconductor materials containing elemental components selected from Group I, Group II, Group III, Group IV and Group VI of the periodic table have been of interest in photovoltaic applications. One particular form of such semiconductor material is composed of various combinations of copper, indium, gallium, selenium, and sulfur, including CIGS(S), (e.g., Cu(In,Ga)(S,Se)₂ or CuIn₁₋ₓGaₓ(S_{y}Se_{1-y})ₖ (where 0≦x≦1, 0≦y≦1 and k is approximately 2)). CIGS(S)-based semiconductor materials are typically fabricated in the form of polycrystalline thin films for use in photovoltaic devices.

The Cu(In,Ga)(S,Se)₂-type thin films for solar applications are typically manufactured by co-evaporating or co-sputtering copper, indium, gallium, and selenium (and optionally sulfur) onto a heated substrate, or depositing particles of the precursor materials onto a substrate, followed by sintering in situ. The resulting polycrystalline thin film composition may be further processed to tailor the defect structure and/or improve performance. The final thin film composition is incorporated into a photovoltaic device as an absorber layer, which is usually carried on glass sheets with a layer of conductive metal (e.g., molybdenum) disposed therebetween. Current manufacturing techniques do not provide the ability to precisely control the concentration of certain elemental components such as, for example, selenium during the formation of the polycrystalline composition. This inability to control concentration contributes to process variability and limits production yield.

In view of the foregoing problems, there is a need for a device and a method for making a polycrystalline composition, which provides more precise control of the concentration of particular chemical elements or compounds during the crystallization process, and enhances the concentration of such chemical elements/compounds in the resulting composition. By reducing process variability in making such materials, the production yield is enhanced while lowering overall costs. There is a need for a device and a method for making a polycrystalline composition exhibiting improved crystalline structure, nanostructure and other desirable electronic properties, especially for use in photovoltaic applications.

### SUMMARY OF THE INVENTION

The present invention relates generally to a device and a method for making a polycrystalline composition. The method of the present invention generally includes processing a precursor material in the presence of a precursor vapor comprising an element or compound supplied at a preselected partial pressure to promote the formation of the desired polycrystalline composition from the combination of the precursor material and the precursor vapor. By varying the partial pressure of the precursor vapor during the process, the concentration of the corresponding element or compound in the product can be controlled more precisely. As a result, the present invention reduces process variability for improved production yield at lower costs. This is an improvement over processes where the particular element or compound is pre-deposited in the precursor material.

The device of the present invention includes at least one heating chamber. Each heating chamber being arranged in series has associated therewith heating means and means for supplying a precursor vapor at a desired partial pressure. There is also provided means for conveying a precursor material through the heating chamber(s). Optionally, the device includes at least one cooling chamber arranged in series, and means for conveying the precursor material from the series of at least one heating chamber through the series of at least one cooling chamber.

In a further embodiment of the present invention, each cooling chamber includes means for supplying a precursor vapor therein at a desired partial pressure. The device may be adapted for processing under vacuum or atmospheric conditions. Under vacuum conditions, mechanical valves are provided between the chambers to isolate the individual chambers from one another. Under atmospheric conditions, a curtain of inert gas (e.g., nitrogen) is maintained between the chambers to similarly isolate the individual chambers from one another.

In one aspect of the present invention, there is provided a method for making a polycrystalline composition, which includes the steps of:

a) preparing a precursor material;

b) heating the precursor material to a temperature in the presence of a precursor vapor supplied from a source at a preselected partial pressure, for a sufficient time to initiate an interaction between the precursor material and precursor vapor to form a heated precursor material; and

c) cooling the heated precursor material at a predetermined cooling rate to yield the polycrystalline composition.

In another aspect of the present invention, there is provided a device for making a polycrystalline composition, which includes:

at least one heating chamber, each being arranged in series and having associated therewith heating means and means for supplying a precursor vapor at a desired partial pressure to a corresponding heating chamber; and

means for conveying a precursor material through the series of at least one heating chamber to enable the precursor material to come into operable contact with the precursor vapor.

### BRIEF DESCRIPTION OF THE DRAWINGS

The following drawing is illustrative of embodiments of the present invention and is not intended to limit the invention as encompassed by the claims forming part of the application.

FIG. 1 is a schematic diagram of a device for making a polycrystalline product from a precursor material in accordance with one embodiment of the present invention.

### DETAILED DESCRIPTION OF THE INVENTION

The present invention is generally directed to a device and a method for making a polycrystalline composition. The method of the present invention generally includes processing a precursor material in the presence of a precursor vapor composed of an element or compound supplied at a preselected partial pressure to promote the formation of the desired polycrystalline composition from the combination of the precursor material and the precursor vapor. By varying the partial pressure of the precursor vapor during the process, the concentration of the corresponding element or compound in the product can be controlled more precisely. As a result, the present invention reduces process variability for improved production yield at lower costs. This is an improvement over processes where the particular element or compound is pre-deposited in the precursor material.

The method of the present invention can be used for making polycrystalline compositions in the form of thin films layers exhibiting desired crystalline structure, nanostructure and other electronic properties using a precursor product which may be deposited as one or more layers on a substrate wherein the polycrystalline composition is the product formed from the combination of the precursor material and a precursor vapor present at a preselected partial pressure.

The present method overcomes the problems associated with processes where the precursor materials are deposited and reacted simultaneously. The present process separates the material deposition from a reaction process wherein the precursor vapor is placed in operable contact with the precursor material under conditions including partial pressure that facilitate controlled product development (i.e., enables controlled interaction of the precursor material and precursor vapor). Thus, two discrete steps are used for improving management of the process requirements for each step.

The method of the present invention will be described in context of the fabrication of a semiconductor layer, coating or film for use in, for example, a photovoltaic device and/or system. However, it will be understood that the process of the present invention can be used in various applications including, but not limited to, the fabrication of a composition layer, coating or film that may be used in a subassembly, which in turn may be used in a larger assembly, or the fabrication of a superconductor layer, coating or film for use in, for example, an electronic device and/or system.

In one embodiment of the present invention, there is provided a method for making a polycrystalline composition, which include the steps of a) preparing a precursor material, b) heating the precursor material to a temperature in the presence of a precursor vapor supplied from a source at a preselected partial pressure, for a sufficient time to initiate an interaction between the precursor material and precursor vapor to form a heated precursor material, and c) cooling the heated precursor material at a predetermined cooling rate to yield the polycrystalline composition. Prior to heating, the precursor material may be placed on a support substrate.

In the present invention, the method may be implemented in a vacuum environment or at atmospheric pressure provided that the preselected partial pressure of the precursor vapor is maintained as described.

The term “precursor material” as used herein refers to any non-vapor form of an element or compound for processing into a polycrystalline composition via the device and method of the present invention. The precursor material may be placed, supported or deposited on a suitable support material or a substrate. The substrate may be selected from glass, ceramic, metal, polymer and combinations thereof. Preferably, the substrate is metal coated glass (e.g., molybdenum coated glass).

The term “precursor vapor” as used herein refers to any vapor form of an element or compound intended to interact with the precursor material forming part of the final polycrystalline composition. The precursor vapor is supplied at a preselected partial pressure in operable contact with the precursor material wherein the precursor vapor interacts (e.g., diffuses through and/or reacts) with the precursor material during processing into a polycrystalline composition.

The term “polycrystalline composition” also referred to as “precursor product”, or “reaction product” is the material formed from the interaction of the precursor material and the precursor vapor under the conditions of the present invention.

The term “partial pressure” as used herein refers to the partial pressure of the precursor vapor established within a volume of space through which the concentration of the element or compound making up the precursor vapor in the precursor material can be controlled during processing into the polycrystalline composition.

In the present invention, the precursor material and precursor vapor may be selected from any chemical element or compound capable of assuming a polycrystalline structure upon interaction with each other. The precursor material and precursor vapor may have the same or different chemical composition. In a preferred embodiment of the present invention, the precursor material and precursor vapor are selected from elements of Group I, Group II, Group III, Group IV and Group VI in the periodic table, and mixtures thereof.

Examples of Group I elements include copper, silver, and gold. Examples of Group II elements include zinc and cadmium. Examples of Group III elements include indium, gallium, and aluminum. Examples of Group IV elements include tin, germanium, and silicon. Examples of Group VI elements include selenium, sulfur, and tellurium.

More preferred combinations of precursor material and precursor vapor include those selected from:

a) Group I, Group III and Group VI (e.g., copper indium gallium selenide (CIGS));

b) Group II and Group VI (e.g., cadmium telluride (CdTe)); and

c) Group I, Group II, Group IV and Group VI (e.g., copper zinc tin sulfide (CZTS)).

In one embodiment of the present invention, one or more layers of precursor material are deposited on a support material or substrate. The layers of precursor material may be disposed in a stacked or laminate arrangement. The precursor material and the precursor vapor may be selected from a chemical element, a binary compound, a ternary compound, a multinary compound, or combinations thereof.

The precursor material may be deposited on the substrate through vacuum deposition techniques, atmospheric-pressure deposition, and the like. Examples of vacuum deposition techniques include, but are not limited to, chemical vapor deposition (CVD), atomic layer deposition (ALD), chemical solution deposition (CSD), plating, physical vapor deposition (PVD), and the like. Examples of PVD processes include, but are not limited to, thermal evaporation, electron-beam evaporation, ion beam deposition (IBD), molecular beam epitaxy (MBE), pulsed laser deposition, sputtering, and the like. Examples of atmospheric-pressure deposition include, but are not limited to, ultrasonic or pneumatic atomization spraying, inkjet spraying, direct writing, screen printing, slot die extrusion coating, and the like.

The one or more layers of precursor material are interacted with a precursor vapor at a preselected partial pressure. The resulting combination is rapidly heated to a temperature referred herein as “reaction temperature” sufficient to allow the precursor material and precursor vapor to interact and thereby transform the precursor material into a reaction product. The reaction temperature is at least about 100° C., more preferably from about 300° C. to 1000° C., and most preferably from about 400° C. to 700° C. Optionally, the precursor material is preheated to a preheating temperature, preferably at about 100° C. At the reaction temperature, the preselected partial pressure of the precursor vapor is in the range of from about 1.0 mTorr to 200 Torr, and preferably from about 1 Torr to 50 Torr.

The heating process promotes interaction between adjacent layers of precursor material and the precursor vapor. The interaction can be chemical (e.g., reactants forming a product) and/or physical (e.g., molecular diffusion, two polymers intermingling to form a copolymer or two metals diffusing together to form a solid solution). The precursor material and precursor vapor are maintained at the reaction temperature for a residence time sufficient to achieve a desired concentration of precursor vapor within the precursor material. In the present invention, the residence time is determined by several factors, including but not limited to, the transport/incorporation/diffusion of precursor vapor, the speed of chemical/physical interaction between precursors, and the desired final property of the reacted film including material concentration gradients, elemental gradients, defect structures, crystal formation, and morphology.

In one embodiment of the present invention, the precursor material and the precursor vapor are maintained at the reaction temperature for a time in the range of from about 1 second to about 180 minutes, and preferably from about 2 second to 30 minutes.

It is noted that the heating process may be implemented in a single stage or in multiple stages depending on the desired characteristics of the final product. The reaction temperature, the precursor vapor, the partial pressure of the precursor vapor, or residence time can be varied or maintained as needed from one stage to the next.

The heated product of the precursor material and precursor vapor is then cooled down at a controlled rate to ambient temperature to produce the resulting polycrystalline composition. In one embodiment of the present invention, the residence time for cooling can be in the range of from about 30 seconds to 180 minutes, and preferably from about 1 minute to 60 minutes. It is noted that the cooling process may be implemented in a single stage or in multiple stages. The cooling rate of the heated product is at least 0.5° C./s, preferably in the range of from about 0.5° C./s to 15° C./s, and more preferably, in the range of from about 1° C./s to 5° C./s. Cooling may be achieved by exposing the heated product to an inert gas flux (e.g., nitrogen gas).

Optionally, the heated product is cooled to a temperature above ambient. During this optional cooling step exposure to the precursor vapor may continue at the same or different partial pressure. In a preferred embodiment of the present invention, when the heated product is at a temperature of from about 325° C. to 675° C., the partial pressure of the precursor vapor is in the range of from about 1.0 mTorr to 200 Torr, and more preferably in the range of from about 1.0 mTorr to 50 Torr. At the temperature of from about 0° C. to 325° C. for the heated product, the partial pressure of the precursor vapor is in the range of from about 0 mTorr to 1 Torr, and more preferably in the range of from about 0 mTorr to 1 mTorr.

In another embodiment of the present invention, there is provided a device for making a polycrystalline composition, which includes at least one heating chamber, each being arranged in series and having associated therewith heating means, means for supplying a precursor vapor at a desired partial pressure, and means for conveying a precursor material through the series of at least one heating chamber.

Optionally, the device includes at least one cooling chamber arranged in series, and means for conveying the precursor material before and during interaction with the precursor vapor from the series of at least one heating chamber through the series of at least one cooling chamber. In a further embodiment of the present invention, each cooling chamber includes means for supplying a precursor vapor at a desired partial pressure to a corresponding cooling chamber.

The device of the present invention may be adapted for processing under vacuum or atmospheric conditions. Under vacuum conditions, mechanical valves are provided between the chambers to isolate the individual chambers from one another. Under atmospheric conditions, a curtain of inert gas (e.g., nitrogen) is maintained between the chambers to similarly isolate the individual chambers from one another.

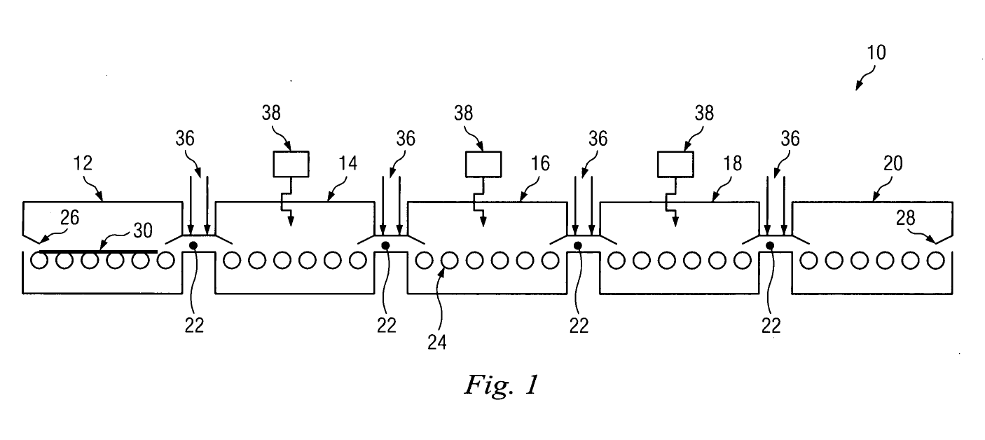

Referring to FIG. 1, a schematic diagram of an illustrative device of the present invention, identified generally by reference numeral 10, is shown for one embodiment of the present invention. The device 10 is configured for implementing the method of the present invention as described above. The device 10 is constructed from a suitable refractory material exhibiting mechanical and thermal properties capable of sustaining partial vacuum environments and enduring high temperature conditions. Such materials for the device can be selected from ceramics, graphite, titanium, steel, and the like.

The device 10 includes a preheat chamber 12, a first heating chamber 14, a second heating chamber 16, a first cooling chamber 18 and a second cooling chamber 20, each linked in series with one another via interconnecting corridors 22. The preheat chamber 12, and the first and second heating chambers 14 and 16, respectively, each include an adjustable heating element (not shown) for raising the temperature of the chambers 12, 14, and 16. The first and second cooling chambers 18 and 20, respectively, each include an adjustable cooling element (not shown) for lowering the temperature of the chambers 18 and 20. The operator can set the temperature of each chamber 12, 14, 16, 18, and 20 independently as required.

The device 10 further includes a conveyor system 24 extending from an inlet 26 of the preheat chamber 12, through preheat chamber 12, the first heating chamber 14, the second heating chamber 16, the first cooling chamber 18, and the second cooling chamber 20, and to an outlet 28 of the second cooling chamber 20. The conveyor system 24 is adapted to convey a substrate 30 (e.g., glass, ceramic, metal, polymer) carrying a precursor material (e.g., layers of copper, indium and gallium) through the device 10 from the inlet 26 to the outlet 28. The conveyor system 24 can be programmed to move and hold the substrate 30 within a corresponding chamber for a specified residence time prior to moving to the next chamber. The operator can vary the residence time of each chamber. The inlet 26 and the outlet 28 may each include a gate valve for opening and closing entry to pass the substrate 30 into and out of the device 10, respectively.

The chambers 12, 14, 16, 18, and 20 of the device 10 can be operated under atmospheric pressure conditions or under partial vacuum conditions. Under atmospheric pressure conditions, the device 10 utilizes a plurality of inert gas curtains 36 each located at a corresponding interconnecting corridor 22 to isolate the chamber atmosphere from the ambient atmosphere. For partial vacuum conditions, the device 10 includes a plurality of gate valves (not shown) each disposed between adjacent chambers at corresponding interconnecting corridors 22 to provide sealed volumes for evacuation, while maintaining desired partial vacuum pressures during passing of the substrate 30 between adjacent chambers, and a vacuum pump (not shown) to at least substantially evacuate the atmosphere from each of the chambers 12, 14, 16, 18, and 20. The operator can vary the background pressure of the chambers 12, 14, 16, 18, and 20 independently as needed.

The device 10 further includes a precursor vapor source 38 adapted for supplying a precursor vapor (e.g., selenium) at a preselected partial pressure to a corresponding chamber 14, 16, or 18 under both atmospheric pressure and partial vacuum conditions. The amount of precursor vapor in the system is preset for the preselected partial pressure associated with the thermal profile and pressure profile of the environment. The chambers 14, 16, and 19 each include partial precursor vapor pressure detection devices (not shown) to indicate the partial pressure of the precursor vapor. The partial pressure of the precursor vapor may be monitored and regulated manually or through automated means using the partial precursor vapor detection devices (not shown).

In the event that the partial pressure of the precursor vapor falls below a preset amount, precursor vapor may be released from the corresponding precursor vapor source 38 to raise the partial pressure. When the partial pressure rises above a preset amount, the precursor vapor can be removed by increasing the flow in the inert gas curtain at the corresponding corridor 22, when the device 10 is operating under the atmospheric pressure conditions. Under partial vacuum operation, the gate valves can be opened to introduce a quantity of an inert gas prior to re-establishing the partial vacuum pressure in order to reduce the elevated partial pressure of the precursor vapor gas. The operator can set the preselected partial pressure of the precursor vapor in each of the chambers 14, 16 and 18 as required.

As shown in FIG. 1, the operation of the device 10 will be described in association with making copper indium gallium selenide (CIGS)-based polycrystalline compositions. It will be understood that the present method is applicable for making any polycrystalline composition utilizing precursor materials including those described above and others. Stacked layers of copper, indium and gallium are deposited on the substrate 30 composed of molybdenum-coated glass. In one embodiment of the present invention, the precursor material includes a CIGS precursor stack comprising a stack or laminate of thin films composed of multinary (preferably binary and ternary) metal selenides or metal sulfides, where the metals are copper, indium and/or gallium. The substrate 30 carrying the precursor material is introduced into the preheat chamber 12 via the gate valve of inlet 26. The preheat chamber 12 heats the substrate 30 to a preheat temperature for a predetermined residence time.

The conveyor system 24 moves the substrate 30 having thereon the precursor material to the first heating chamber 14 where the precursor material is rapidly heated to a reaction temperature in the presence of selenium gas (precursor vapor) at a preselected partial pressure for a predetermined residence time. The selenium gas as a precursor vapor supplies a source of selenium needed for incorporation into the precursor material and provides the necessary overpressure to ensure sufficient content of selenium in the reacted product. In this manner, any selenium released from the precursor material during the heating process is substantially minimized particularly at the final reaction temperatures, thus avoiding selenium deficiency or defects in the final reaction product. The residence time in the chamber is controlled in part by the selenium partial pressure and its uniformity of the selenium gas in the chamber. A non-optimal residence time may yield a non-optimal reaction temperature or heating profile, thus causing inferior chemical composition and/or defect states in the reacted product.

The substrate 30 is thereafter moved by the conveyor system 24 to the second heating chamber 16 and maintained at the reaction temperature in the presence of the selenium gas at the preselected partial pressure for a predetermined residence time to yield a reaction product (i.e., a product that results from the interaction of the precursor material and precursor vapor at elevated temperatures and prior to the cool down cycle). The second heating chamber 16 provides a temperature profile, minimizing any temperature gradients, and allows the operator to control the selenium gas partial pressure independently from the first heating chamber 14.

The substrate 30 is then moved to the first cooling chamber 18 where the reaction product is cooled down from the reaction temperature to an intermediate temperature above ambient for a predetermined residence time, while in the presence of the selenium gas at a preselected partial pressure. The first cooling chamber 18 provides a controlled rate of cooling suitable for initiating formation of a polycrystalline composition characterized by relatively large grains and minimal surface defects. The first cooling chamber 18 allows the operator, to control the selenium gas partial pressure independently from the first and second heating chambers 14 and 16.

In one embodiment of the present invention, when the reaction product is cooling down to the intermediate temperature to initiate formation of the polycrystalline composition, the partial pressure of the selenium gas is in the range of from about 1.0 mTorr to 200 Torr, and preferably from about 1.0 mTorr to 50 Torr. When the reaction product is cooling down from the intermediate temperature the partial pressure of the selenium gas is in the range of from about 0 to 200 Torr, and preferably from about 0 to 1 Torr.

The substrate 30 carrying the reaction product is then moved to the second cooling chamber 20 where further cooling takes place down to ambient temperature to yield the polycrystalline composition. A cooled inert gas flux can be passed over the cooling reaction product to accelerate the cooling rate. Once at ambient temperature, the substrate 30 with the polycrystalline composition can be removed from the device 10 through the outlet 28.

### EXAMPLES

### Example 1

### Polycrystalline Composition Produced Via a Device of the Present Invention Under Partial Vacuum Conditions

Although the present invention is described in context of copper indium gallium selenide (CIGS)-based polycrystalline compositions, it will be understood that the present invention may be utilized to make any polycrystalline composition with other precursor materials as described above.

As shown in FIG. 1, a precursor material containing copper, indium, gallium, and selenium is placed on a substrate composed of glass coated with a molybdenum film. The precursor material supported on the substrate is placed on a conveyor at the inlet of the device. The substrate with the precursor material is introduced through a gate valve into the preheat chamber which is maintained at about 100° C. All of the chambers are maintained at a background pressure of less than about 1 mTorr, and any pressure increase is mainly due to the selenium partial pressure produced by an external selenium gas source. The gate valves located on each side the chambers are normally in a “closed” position to maintain the desired partial vacuum pressures and selenium partial pressures within the first and second heating chambers and the first cooling chamber. The gate valves only open for moving the substrate with the precursor material between corresponding adjacent chambers for further processing of the precursor material.

After loading the substrate with the precursor material into the preheat chamber, the precursor material is heated to a preheat temperature of about 100° C. Then the preheat chamber is pumped down to a partial vacuum pressure of about 1 mTorr pressure prior to moving the substrate with the precursor material into the first heating chamber. The first heating chamber maintains a steady isothermic environment of about 800° C. with an external selenium gas source supplying selenium gas at a partial pressure of about 20 Torr. After the gate valve between preheat chamber and the first heating chamber closes, the substrate with the precursor material remains in the first heating chamber for about 55 seconds where the precursor material is rapidly heated to a uniform temperature of about 600° C. in the presence of the selenium gas to yield a reaction product.

The gate valve between the first and second heating chambers is opened, and the substrate with the reaction product is moved to the second heating chamber. The gate valve is then closed. The second heating chamber is maintained at a steady isothermic environment of about 600° C. with an external selenium gas source supplying selenium gas at a partial pressure of about 20 Torr. The substrate with the reaction product remains in the second heating chamber for about 2 minutes.

The gate valve between the second heating chamber and the first cooling chamber is opened, and the substrate with the reaction product is moved to the first cooling chamber. The gate valve is then closed. The first cooling temperature is maintained at a temperature less than the temperature of the second heating chamber to initiate rapid cool down within a controlled selenium partial pressure environment. During about the first 2 minutes of cooling, as the temperature of the reaction product drops down from about 600° C. down to about 450° C., the external selenium gas source maintains a selenium partial pressure of about 20 Torr. As the reaction product further cools from about 450° C. to about 300° C. in about 2.5 minutes, the selenium partial pressure in the first cooling chamber is reduced to less than about 1 mTorr.

The gate valve between the first and second cooling chambers is opened, and the substrate with the reaction product is moved to the second cooling chamber. A nitrogen gas flux is used to cool the reaction product down to a temperature of about 100° C. in about 1 minute. The pressure within the second cooling chamber is equalized with the ambient atmosphere, and the gate valve at the outlet of the device is opened. The substrate is then conveyed out of the second cooling chamber through the open gate valve having thereon a polycrystalline film of CIGS produced by the reaction of the precursor vapor and the precursor material.

### Example 2

### Polycrystalline Composition Produced Via a Device of the Present Invention under Atmospheric Pressure Conditions

Although the present invention is described in context of copper indium gallium selenide (CIGS)-based polycrystalline compositions, it will be understood that the present invention may be utilized to make any polycrystalline composition utilizing other precursor materials as described above.

As shown in FIG. 1, a precursor material containing copper, indium, gallium and selenium is placed on a substrate composed of glass coated with a molybdenum film. The precursor material and substrate are placed on a conveyor at the inlet of the device. The substrate with the precursor material is introduced through a nitrogen gas curtain at the inlet into the preheat chamber which is maintained at about 100° C. All the chambers are maintained at atmospheric pressure. Nitrogen gas curtains located on each side of the chambers at the interconnecting corridors, are normally in the “on” position to isolate the atmospheres of the chambers from one another. The flow of the nitrogen gas curtains are suspended during the transfer of the substrate between corresponding adjacent chambers for further processing of the precursor material and to minimize disruption of the selenium content on the surface. Once the substrate is moved to the next chamber, the flow of the nitrogen gas curtain is resumed to isolate the individual selenium partial pressures within each of the chambers.

After loading the substrate with the precursor material in the preheat chamber, the precursor material is heated to the preheat temperature of about 100° C. Upon preheat the precursor material, the nitrogen gas curtain between the preheat chamber and the first heating chamber is suspended. The conveyor moves the substrate with the precursor material to the first heating chamber. The first heating chamber maintains a steady isothermic environment of about 800° C. with an external selenium gas source supplying selenium gas at a partial pressure of about 20 Torr. The nitrogen gas curtain between the preheat chamber and the first heating chamber is restored. The substrate with the precursor material remains in the first heating chamber for about 55 seconds where the precursor material is rapidly heated to a uniform temperature of about 600° C. in the presence of the selenium gas to yield a reaction product.

The nitrogen gas curtain between the first and second heating chambers is suspended, and the substrate with the reaction product is moved to the second heating chamber. The nitrogen gas curtain is then restored. The second heating chamber is maintained at a steady isothermic environment of about 600° C. with an external selenium gas source supplying selenium gas at a partial pressure of about 20 Torr. The substrate with the reaction product remains in the second heating chamber for about 2 minutes. The nitrogen gas curtain between the second heating chamber and the first cooling chamber is suspended, and the substrate with the reaction product is moved to the first cooling chamber. The nitrogen gas curtain is then restored. The first cooling chamber is maintained at a temperature less than the temperature of the second heating chamber to initiate rapid cool down within a controlled selenium partial pressure environment.

During the first 2 minutes of cooling, as the temperature of the reaction product drops from about 600° C. to about 450° C., the external selenium gas source maintains a selenium partial pressure of about 10 Torr. As the reaction product cools from about 450° C. to about 300° C. in about 2.5 minutes, the selenium partial pressure in the first cooling chamber is reduced to less than about 1 mTorr.

The nitrogen gas curtain between the first and the second cooling chambers is suspended, and the substrate with the reaction product is moved to the second cooling chamber. A nitrogen gas flux is used to cool the reaction product down to a temperature of about 100° C. in about 1 minute. The substrate is then conveyed out of the second cooling chamber through the outlet of the device having thereon a polycrystalline film of CIGS produced by the reaction of the precursor vapor and the precursor material.

The foregoing discussion discloses and describes merely exemplary embodiments of the present invention. One skilled in the art will readily recognize from such discussion, and from the accompanying drawing and claims, that various changes, modifications and variations can be made therein without departing from the spirit and scope of the invention as defined in the following claims.

What is claimed is:

1. A method for making a polycrystalline composition, said method comprising the steps of:
a) preparing a precursor material;
b) heating the precursor material to a reaction temperature in the presence of a precursor vapor supplied from a source at a preselected partial pressure, for a sufficient time to initiate an interaction between the precursor material and precursor vapor to form a heated precursor material; and
c) cooling the heated precursor material at a predetermined cooling rate to yield the polycrystalline composition.

2. The method of claim 1 further comprising placing the precursor material on a substrate.

3. The method of claim 1 wherein the substrate is selected from the group consisting of glass, ceramic, metal, polymer and combinations thereof.

4. The method of claim 3 wherein the substrate is metal coated glass.

5. The method of claim 1 wherein the cooling step further comprises cooling the heated precursor material in the presence of the precursor vapor supplied at a partial pressure.

6. The method of claim 1 wherein the reaction temperature is at least about 100° C.

7. The method of claim 6 wherein the reaction temperature is in the range of from about 300° C. to 1000° C.

8. The method of claim 7 wherein the reaction temperature is in the range of from about 400° C. to 700° C.

9. The method of claim 1 wherein preselected partial pressure of the precursor vapor is in the range of from about 1.0 mTorr to 200 Torr.

10. The method of claim 9 wherein the preselected partial pressure is in the range of from about 1 Torr to 50 Torr.

11. The method of claim 1 wherein the cooling rate is at least 0.5° C./s.

12. The method of claim 11 wherein the cooling rate is in the range of from about 0.5° C./s to 15° C./s.

13. The method of claim 12 wherein the cooling rate is in the range of from about 1° C./s to 5° C./s.

14. The method of claim 1 wherein the precursor material comprises a member selected from the group consisting of Group I elements, Group II elements, Group III elements, Group IV elements and Group VI elements, and mixtures thereof.

15. The method of claim 1 wherein the precursor vapor is selected from the group consisting of Group I elements, Group II elements, Group III elements, Group IV elements and Group VI elements, and mixtures thereof.

16. The method of claim 14 wherein the Group I elements are selected from the group consisting of copper, silver, gold and combinations thereof.

17. The method of claim 14 wherein the Group II elements are selected from the group consisting of zinc, cadmium and combinations thereof.

18. The method of claim 14 wherein the Group III elements are selected from the group consisting of indium, gallium, aluminum and combinations thereof.

19. The method of claim 14 wherein the Group IV elements are selected from the group consisting of tin, germanium, silicon, and combinations thereof.

20. The method of claim 14 wherein the Group VI elements are selected from the group consisting of selenium, sulfur, tellurium, and combinations thereof.

21. The method of claim 1 further comprising the step of preheating the precursor material to a preheating temperature.

22. The method of claim 1 wherein step b) further comprises:
transferring the precursor material to a first heating chamber maintained at a first heating chamber temperature with the precursor vapor supplied at a first partial pressure;
holding the precursor material in the first heating chamber for a first predetermined time;
transferring the precursor material to a second heating chamber maintained at a second heating chamber temperature with the precursor vapor supplied at a second partial pressure; and
holding the precursor material in the second heating chamber for a second predetermined time.

23. The method of claim 1 wherein step c) further comprises:
transferring the heated precursor material to a first cooling chamber containing the precursor vapor supplied at a preselected partial pressure;
cooling the heated precursor material at a first cooling rate in the first cooling chamber to a temperature above ambient;
transferring the heated precursor material to a second cooling chamber; and
cooling the heated precursor material at a second cooling rate in the second cooling chamber to ambient.

24. The method of claim 23 wherein preselected partial pressure of the precursor vapor in the first cooling chamber is in the range of from about 1.0 mTorr to 200 Torr, when the heated precursor material is at about 325° C. to 675° C.

25. The method of claim 24 wherein preselected partial pressure of the precursor vapor in the first cooling chamber is in the range of from about 1.0 mTorr to 50 Torr.

26. The method of claim 25 wherein preselected partial pressure of the precursor vapor in the first cooling chamber is in the range of from about 0 mTorr to 1 Torr, when the heated precursor material is at about 0° C. to 325° C.

27. The method of claim 26 wherein preselected partial pressure of the precursor vapor in the first cooling chamber is in the range of from about 0 mTorr to 1 mTorr.

28. The method of claim 1 wherein the time for maintaining the precursor material at the reaction temperature is in the range of from about 1 second to 180 minutes.

29. The method of claim 1 wherein the time for cooling the heated precursor material is in the range of from about 30 second to 180 minutes.

30. A device for making a polycrystalline composition, comprising:
at least one heating chamber, each being arranged in series and having associated therewith heating means and means for supplying a precursor vapor at a desired partial pressure to a corresponding heating chamber; and
means for conveying a precursor material through said series of at least one heating chamber.

31. The device of claim 30 further comprising:
at least one cooling chamber arranged in series; and
means for conveying the precursor material from said series of at least one heating chamber through said series of at least one cooling chamber.

32. The device of claim 31 wherein each cooling chamber comprises means for supplying a precursor vapor at a desired partial pressure to a corresponding cooling chamber.
